(19) United States
(12) Patent Application Publication
(10) Pub. No.: US 2018/0019361 A1
(43) Pub. Date: Jan. 18, 2018

(54) PHOTOELECTRIC CONVERSION DEVICE, MANUFACTURING METHOD FOR PHOTOELECTRIC CONVERSION DEVICE, AND PHOTOELECTRIC CONVERSION MODULE

(71) Applicant: Kaneka Corporation, Osaka (JP)

(72) Inventors: Ryota Mishima, Osaka (JP); Masashi Hino, Osaka (JP); Hisashi Uzu, Osaka (JP); Tomomi Meguro, Osaka (JP)

(73) Assignee: Kaneka Corporation, Osaka (JP)

(21) Appl. No.: 15/717,303

(22) Filed: Sep. 27, 2017

Related U.S. Application Data
(63) Continuation of application No. PCT/JP2016/059859, filed on Mar. 28, 2016.

(30) Foreign Application Priority Data
Mar. 31, 2015 (JP) 2015-071103

(51) Int. Cl. H01L 31/0747; H01G 9/20; H01G 9/00; H01L 31/0216; H01L 31/0236

(52) U.S. Cl. CPC H01L 31/0747; H01G 9/2009; H01G 9/0029; H01L 31/02363; H01L 31/02168

(57) ABSTRACT

A photoelectric conversion device includes, arranged in the following order from a light-receiving side: a transparent electroconductive layer; a first photoelectric conversion unit that is a perovskite-type photoelectric conversion unit; and a second photoelectric conversion unit. The first photoelectric conversion unit includes, arranged in the following order from the light-receiving side: a hole transporting layer; a light absorbing layer including a photosensitive material of perovskite-type crystal structure represented by general formula RNH₃MX₃ or HC(NH₂)₂MX₃; and an electron transporting layer. The second photoelectric conversion unit includes a light absorbing layer having a bandgap narrower than a bandgap of the light absorbing layer in the first photoelectric conversion unit. A product of a resistivity ρ and a thickness t of the hole transporting layer satisfies ρt≧0.1 μQ·m². The transparent electroconductive layer is in contact with the hole transporting layer.

### TECHNICAL FIELD

The present invention relates to a photoelectric conversion device, a manufacturing method of a photoelectric conversion device and a photoelectric conversion module.

A solar cell utilizing an organic metal perovskite crystal material (perovskite-type solar cell) can provide a high conversion efficiency. A large number of reports have recently been published on improvement on conversion efficiency of a solar cell utilizing a perovskite crystal material in a light absorbing layer (e.g., Non-Patent Document 1 and Patent Document 1). In one configuration example of the perovskite-type solar cell, a transparent substrate, a transparent electroconductive layer, a blocking layer (electron transporting layer) composed of TiO₂ etc., a light absorbing layer with a perovskite crystal material formed on a porous surface of a metal oxide such as TiO₂, a hole transporting layer and a metal electrode layer are provided in this order from the light-receiving side.

As the organic metal, a compound represented by a general formula RNH₃MX₃ or HC(NH₂)₂MX₃ (where R is an alkyl group, M is a divalent metal ion, and X is a halogen) is used. Spectral sensitivity characteristics are known to vary depending on the halogen and/or the ratio of the halogen (e.g., Non-Patent Document 2).

A perovskite crystal material, such as CH₃NH₃PbX₃ (X: halogen), can be used to form a thin-film at low cost using a solution application technique, such as spin coating. Thus, attention has been directed to a perovskite-type solar cell utilizing such a perovskite crystal material, as a low-cost and high-efficiency next generation solar cell. Furthermore, a perovskite-type solar cell has also been developed that incorporates, as a light absorbing material, CH₃NH₃SnX₃ containing tin in place of lead (e.g., Non-Patent Document 3).

### PRIOR ART DOCUMENTS

### Patent Documents

Patent Document 1: JP 2014-72327 A

### Non-Patent Documents

Non Patent Document 1: G. Hodes, Science, 342, 317-318 (2013).
Non Patent Document 2: A. Kojima et. al., J. Am. Chem. Soc., 131, 6050-6051 (2009).
Non Patent Document 3: F. Hao et al., Nat. Photonics, 8, 489-494 (2014).

### SUMMARY OF THE INVENTION

### Problems to be Solved by the Invention

As disclosed in Non-Patent Document 2, a perovskite crystal material exhibits a spectral sensitivity characteristic at wavelengths shorter than 800 nm, and thus absorbs little infrared light having wavelengths greater than 800 nm. Thus, to improve efficiency of a perovskite-type solar cell, it is important to effectively use long-wavelength light. For example, a combination of a perovskite-type solar cell and a solar cell having a bandgap narrower than that of the perovskite-type solar cell allows long-wavelength light to be used by the solar cell having a narrower bandgap. This is thought to achieve a solar cell with higher efficiency

One known photoelectric conversion device including a combination of multiple solar cells is a tandem-type photoelectric conversion device in which photoelectric conversion units (solar cells) having different bandgaps are stacked. A tandem-type photoelectric conversion device includes a photoelectric conversion unit (front cell) having a wider bandgap provided on a light-receiving side, and a photoelectric conversion unit (rear cell) having a narrower bandgap provided at the rear side of the front cell.

A stacked-type photoelectric conversion device including a combination of a perovskite-type solar cell (hereinafter, also referred to as a perovskite-type photoelectric conversion unit) and another photoelectric conversion unit has rarely been reported previously. Thus, there is currently no useful findings for a configuration and disposition of the perovskite-type photoelectric conversion unit in a stacked-type photoelectric conversion device

Examples of the solar cell in which the bandgap of a light absorbing layer is narrower than the bandgap of a light absorbing layer in a perovskite-type solar cell include solar cells in which a light absorbing layer is made of crystalline silicon. In particular, a heterojunction solar cell having silicon-based thin-films on both surfaces of a single-crystalline silicon substrate shows high conversion efficiency. Thus, it is considered that a stacked-type photoelectric conversion device in which a perovskite-type photoelectric conversion unit is disposed on the light-receiving side, and a heterojunction solar cell (hereinafter, also referred to as a heterojunction unit) is disposed at the rear of the perovskite-type photoelectric conversion unit has high conversion efficiency. A heterojunction solar cell is known to have high conversion efficiency when the single-crystalline silicon substrate is n-type, the silicon-based thin-film on the light-receiving side is p-type, and the silicon-based thin-film on the rear side is n-type.

When the rear heterojunction unit includes a p-type silicon-based thin-film on the light-receiving side and n-type silicon-based thin-film on the rear side, the front perovskite-type photoelectric conversion unit is required to have a configuration in which a hole transporting layer and an electron transporting layer are disposed on the light-receiving side and the rear side, respectively, of the light absorbing layer, so that light is incident from the hole transporting layer side. This configuration is different from the configuration of a conventional perovskite-type solar cell. Thus, the configuration of a conventional perovskite-type solar cell with a metal electrode layer provided on a hole transporting layer cannot be employed as it is.

In view of the situations described above, an object of the present invention is to provide a stacked-type photoelectric conversion device in which a perovskite-type photoelectric conversion unit is combined with other photoelectric conversion unit.

### Means for Solving the Problem

The present invention relates to a stacked-type photoelectric conversion device including a first photoelectric conversion unit and a second photoelectric conversion unit in this order from the light-receiving side. The first photoelectric conversion unit is a perovskite-type photoelectric conversion unit, and has a light absorbing layer containing a photosensitive material of perovskite-type crystal structure represented by the general formula RNH₃MX₃ or HC(NH₂)₂MX₃. The first photoelectric conversion unit includes a hole transporting layer, a light absorbing layer and an electron transporting layer, in this order from the light-receiving side.

The second photoelectric conversion unit includes a light absorbing layer having a bandgap narrower than the bandgap of the light absorbing layer in the first photoelectric conversion unit, and thus the second photoelectric conversion unit can more efficiently utilize light having a longer wavelength than the perovskite-type photoelectric conversion unit. Examples of the material of the light absorbing layer in the second photoelectric conversion unit include crystalline silicon (single crystalline, polycrystalline, or microcrystalline) and chalcopyrite-based compounds such as CuInSe₂ (CIS). It is preferred that the second photoelectric conversion unit includes a p-type silicon-based thin-film, conductive single-crystalline silicon substrate and an n-type silicon-based thin-film, in this order from the light-receiving side.

The product ρt of the resistivity ρ and the thickness t of the hole transporting layer in the first photoelectric conversion unit is preferably 0.1 μΩ·m² or more. A light-receiving-side transparent electroconductive layer that is in contact with the hole transporting layer is provided on the light-receiving side of the hole transporting layer.

The work function of the light-receiving-side transparent electroconductive layer is preferably 4.7 to 5.8 eV. The carrier density of the light-receiving-side transparent electroconductive layer is preferably 1×10¹⁹ to 5×10²⁰ cm⁻³. The thickness of the hole transporting layer is preferably 1 to 100 nm.

The present invention also relates to a method for manufacturing the above photoelectric conversion device, and a photoelectric conversion module including the above photoelectric conversion device.

### Effects of the Invention

A hole transporting layer in which the product ρt of the resistivity ρ and the thickness t is larger than specific value is provided on the light-receiving side of a light absorbing layer in a perovskite-type photoelectric conversion unit, and a transparent electroconductive layer is provided in contact with the light-receiving surface of the hole transporting layer, so that a large amount of light arrives at the perovskite-type photoelectric conversion unit and a second photoelectric conversion unit disposed at the rear thereof. Further, electrical connection between the transparent electroconductive layer and the hole transporting layer is improved, and therefore the energy barrier in movement of holes can be lowered. As a result, a photoelectric conversion device having high conversion efficiency is obtained.

### BRIEF DESCRIPTION OF THE DRAWINGS

FIG. 1 is a schematic sectional view of a photoelectric conversion device according to one embodiment of the present invention.

### DESCRIPTION OF EMBODIMENTS

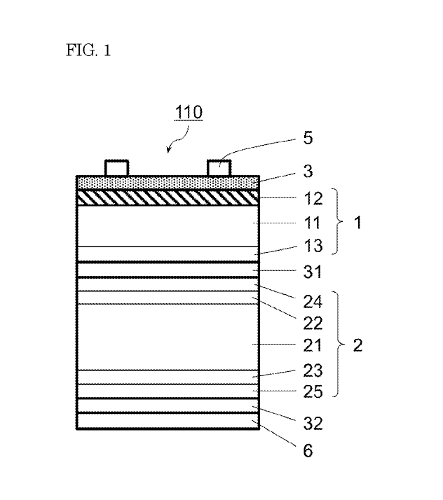

FIG. 1 is a schematic sectional view of a photoelectric conversion device according to one embodiment of the present invention. In FIG. 1, dimensional relations of thickness, length and so on are appropriately changed for clarification and simplification of the drawings, and do not reflect actual dimensional relations. A photoelectric conversion device 110 shown in FIG. 1 is a tandem-type photoelectric conversion device, and includes a collecting electrode 5, a light-receiving-side transparent electroconductive layer 3, a first photoelectric conversion unit 1, an intermediate transparent electroconductive layer 31, a second photoelectric conversion unit 2, a rear-side transparent electroconductive layer 32 and a rear-side metal electrode 6, in this order from the light-receiving side.

(First Photoelectric Conversion Unit)

The first photoelectric conversion unit 1 includes a hole transporting layer 12, a light absorbing layer 11 and an electron transporting layer 13 in this order from the light-receiving side. The first photoelectric conversion unit 1 is a perovskite-type photoelectric conversion unit, and contains a photosensitive material (perovskite crystal material) of perovskite-type crystal structure in the light absorbing layer 11.

As described later, the first photoelectric conversion unit 1 can be formed by a process using a solution etc. The first photoelectric conversion unit 1 can be formed by providing the electron transporting layer 13, the light absorbing layer 11 and the hole transporting layer 12, in order on the second photoelectric conversion unit 2 (on the intermediate transparent electroconductive layer 31 when the intermediate transparent electroconductive layer 31 is formed).

On the second photoelectric conversion unit 2 (the rear side of the light absorbing layer 11), the electron transporting layer 13 is formed. As a material of the electron transporting layer, a known material may be appropriately selected, and examples thereof include titanium oxide, zinc oxide, niobium oxide, zirconium oxide and aluminum oxide. The electron transporting layer may contain a donor. For example, when titanium oxide is used for the electron transporting layer, examples of the donor include yttrium, europium and terbium.

The electron transporting layer may be a dense layer having a smooth structure, or a porous layer having a porous structure. When the electron transporting layer has a porous structure, the pore size is preferably on the nanoscale. Preferably, the electron transporting layer has a porous structure for increasing the active surface area of the light absorbing layer to improve collectiveness of electrons by the electron transporting layer.

The electron transporting layer may be a single layer, or may have a stacking configuration with a plurality of layers. For example, the electron transporting layer may have a double layer structure in which a dense layer is provided on the second photoelectric conversion unit 2-side, and a porous layer is provided on the light absorbing layer 11-side of the first photoelectric conversion unit 1. The thickness of the electron transporting layer is preferably 1 to 200 nm. The electron transporting layer is formed on the second photoelectric conversion unit 2 by, for example, a spraying method etc. using a solution containing an electron transporting material such as titanium oxide.

The compound that forms a perovskite crystal material contained in the light absorbing layer 11 is represented by a general formula RNH₃MX₃ or HC(NH₂)₂MX₃. R is an alkyl group, preferably an alkyl group having 1 to 5 carbon atoms, and particularly preferably a methyl group. M is a divalent metal ion, and preferably Pb or Sn. X is a halogen, such as F, Cl, Br, or I. The three elements X may be a same halogen element, or a mixture of different halogen elements. Spectral sensitivity characteristics may be changed when halogens and/or a ratio between halogens is changed.

The bandgap of the light absorbing layer 11 in the first photoelectric conversion unit 1 is preferably 1.55 to 1.75 eV, more preferably 1.60 to 1.65 eV for making current matching between photoelectric conversion units. For example, when the perovskite crystal material is represented by the formula CH₃NH₃PbI₃₋ₓBrₓ, x is preferably about 0 to 0.85 for ensuring that the bandgap is 1.55 to 1.75 eV, and x is preferably about 0.15 to 0.55 for ensuring that the bandgap is 1.60 to 1.65 eV. The light absorbing layer 11 is formed on the electron transporting layer 13 by, for example, a spin coating method etc. using a solution containing a perovskite crystal material.

The hole transporting layer 12 is provided on the light absorbing layer 11 (the light-receiving side of the light absorbing layer 11). The hole transporting layer 12 is required to have light permeability for causing light to arrive at the light absorbing layer in the first photoelectric conversion unit and the light absorbing layer in the second photoelectric conversion unit.

As a material of the hole transporting layer, a known material may be appropriately selected, and examples thereof include polythiophene derivatives such as poly-3-hexylthiophene (P3HT) and poly(3,4-ethylenedioxythiophene) (PEDOT), fluorene derivatives such as 2,2′,7,7′-tetrakis-(N,N-di-p-methoxyphenylamine)-9,9′-spirobifluorene (Spiro-OMeTAD), carbazole derivatives such as polyvinyl carbazole, triphenylamine derivatives, diphenylamine derivatives, polysilane derivatives and polyaniline derivatives. The hole transporting layer 12 is formed on the light absorbing layer 11 by, for example, a spraying method etc. using a solution containing the abovementioned hole transporting material. Metal oxides such as MoO₃, WO₃ and NiO may also be used as the material of the hole transporting layer. The hole transporting layer may be a single layer, or may have a stacking configuration with a plurality of layers.

The hole transporting layer may contain an additive for reducing the resistivity. Examples of the additive include solid additives such as Li-bis(trifluoromethanesulfonyl)imide (Li-TFSI), liquid additives such as 4-tert-butylpyridine (tBP), and metal complexes containing Co etc. When the hole transporting layer 12 has a small thickness, the content of the additive may be low. For example, the content of the additive in the hole transporting layer 12 may be 0.5 to 10% by volume. It is known that when the content of the additive in the hole transporting layer (except for tBP) is high, a large amount of light having a long wavelength is absorbed in the hole transporting layer. When the content of the additive in the hole transporting layer is reduced, absorption of light by the hole transporting layer decreases, and therefore the amount of light arriving at the light absorbing layer in the first photoelectric conversion unit and the light absorbing layer in the second photoelectric conversion unit increases.

The resistivity ρ of the hole transporting layer 12 is preferably 1×10⁴ Ω·cm or less. The resistivity of the hole transporting layer containing no additives is normally about 1×10⁸ Ω·cm. The resistivity of the hole transporting layer can be reduced to about 1×10³ to 1×10⁴ Ω·cm by the additive. When the content of the additive in the hole transporting layer 12 is low, the resistivity increases to a certain degree. For example, the resistivity ρ of the hole transporting layer 12 may be 5×10⁵ to 1×10⁸ Ω·cm.

When the content of the additive in the hole transporting layer 12 is decreased, light absorption can be reduced, but the resistivity increases. When the thickness of the hole transporting layer 12 is decreased, influences of resistance can be reduced. However, when the hole transporting layer 12 is extremely thin, it no longer functions as a hole transporting layer, so that performance of the photoelectric conversion device is deteriorated. In view of the above, the thickness t of the hole transporting layer 12 is preferably 100 nm or less, more preferably 50 nm or less. The thickness t of the hole transporting layer 12 is preferably 1 nm or more, more preferably 5 nm or more, further preferably 20 nm or more.

The thickness of the hole transporting layer can be measured by transmission electron microscope (TEM) observation of a cross-section. The thickness of the electron transporting layer described above, and the thickness of each of other layers described below can be measured by the same method as described above. When a layer is formed on a textured surface of a silicon substrate etc., which comprises a plurality of projections or recesses such as pyramidal projections or recesses, the direction perpendicular to the slope of the projections or recesses is determined as a thickness direction.

By adjusting the thickness, the constituent material and so on of the hole transporting layer 12, the product ρt of the resistivity ρ and the thickness t can be set to 0.1 μΩ·m² or more. When the value of μt for the hole transporting layer is in the above-mentioned range, the amount of light arriving at the light absorbing layer in the first photoelectric conversion unit and the light absorbing layer in the second photoelectric conversion unit increases, and therefore conversion efficiency can be improved. The value of μt for the hole transporting layer 12 is preferably 1 μΩ·m² or more, more preferably 10 μΩ·m² or more. The upper limit of the value of μt for the hole transporting layer 12 is not particularly limited as long as it is, for example, 100 mΩ·m² or less. The value of μt for the hole transporting layer 12 is preferably 1 mΩ·m² or less, more preferably 100 μΩ·m² or less.

(Light-Receiving-Side Transparent Electroconductive Layer)

In the first photoelectric conversion unit 1, it is necessary to transmit light through the light absorbing layer 11 from the hole transporting layer 12 side, and therefore the transparent electroconductive layer 3 is provided on the light-receiving surface of the hole transporting layer 12. The light-receiving-side transparent electroconductive layer preferably has a conductive oxide as a main component. As the conductive oxide, for example, zinc oxide, indium oxide and tin oxide may be used alone or in complex oxide. From the viewpoints of electroconductivity, optical characteristics and long-term reliability, indium-based oxides including indium oxide are preferable. Among them, those having indium tin oxide (ITO) as a main component are more suitably used. The wording “as a main component” in this specification means that the content is more than 50% by weight, preferably 70% by weight or more, more preferably 85% by weight or more.

A dopant may be added to the transparent electroconductive layer. For example, when zinc oxide is used for the transparent electroconductive layer, examples of the dopant include aluminum, gallium, boron, silicon and carbon. When indium oxide is used for the transparent electroconductive layer, examples of the dopant include zinc, tin, titanium, tungsten, molybdenum and silicon. When tin oxide is used for the transparent electroconductive layer, examples of the dopant include fluorine.

In a perovskite-type solar cell with a metal electrode layer provided in contact with a hole transporting layer, the metal electrode layer has low resistance, and therefore even when electrical connection between the hole transporting layer and the electrode, sufficient conversion efficiency is obtained. In the photoelectric conversion unit 1 with the light-receiving-side transparent electroconductive layer 3 provided on the thin hole transporting layer 12, on the other hand, electrical connection between the light-receiving-side transparent electroconductive layer 3 and the hole transporting layer 12 significantly influences conversion efficiency because the resistivity of the transparent electroconductive layer is higher than that of the metal electrode layer.

By improving electrical connection between the light-receiving-side transparent electroconductive layer 3 and the hole transporting layer 12, conversion efficiency can be improved. Specifically, a difference between the work function of the light-receiving-side transparent electroconductive layer 3 and the ionization potential of the hole transporting layer 12 is preferably small. By reducing a difference between the work function of the transparent electroconductive layer and the ionization potential of the hole transporting layer, the energy barrier in hole transportation is lowered, so that electrical connection between the light-receiving-side transparent electroconductive layer 3 and the hole transporting layer 12 is improved.

The ionization potential of the hole transporting layer is determined by a perovskite crystal material contained in the light absorbing layer. The ionization potential varies depending on the type and amount of a material contained in the hole transporting layer, and is normally about 5.0 to 5.4 eV. Thus, the work function of the light-receiving-side transparent electroconductive layer 3 is preferably 4.7 eV or more, more preferably 4.9 eV or more. The work function of the light-receiving-side transparent electroconductive layer 3 is preferably 5.8 eV or less, more preferably 5.5 eV or less, further preferably 5.3 eV or less. The work function can be measured by an ultraviolet photoelectron spectroscopy (UPS) method.

The carrier density of the light-receiving-side transparent electroconductive layer 3 is preferably 1×10¹⁹ to 5×10²⁰ cm⁻³. The work function tends to increase as the carrier density decreases. When the carrier density of the light-receiving-side transparent electroconductive layer 3 is in the above-mentioned range, a difference between the work function of the light-receiving-side transparent electroconductive layer 3 and the ionization potential of the hole transporting layer 12 decreases, so that electrical connection between the transparent electroconductive layer 3 and the hole transporting layer 12 is improved. The carrier density of the light-receiving-side transparent electroconductive layer 3 is more preferably 2×10²⁰ cm⁻³ or less, further preferably 1×10²⁰ cm⁻³ or less. The carrier density is determined from a Hall mobility measured by a van der Pauw method.

The resistivity of the light-receiving-side transparent electroconductive layer 3 is preferably 1×10⁻⁴ to 5×10⁻³ Ω·cm, more preferably 5×10⁻⁴ to 1×10⁻³ Ω·cm. The thickness of the light-receiving-side transparent electroconductive layer 3 is preferably 10 to 140 nm, more preferably 50 to 100 nm from the viewpoint of transparency, conductivity, reduction of light reflection, and so on. The light-receiving-side transparent electroconductive layer 3 may be a single layer, or may have a stacking configuration with a plurality of layers.

The light-receiving-side transparent electroconductive layer 3 may be either amorphous or crystalline. “Amorphous” refers to those in which no crystal-specific peak is observed in X-ray diffraction. Examples of amorphous ITO include those in which none of the diffraction peaks of (220), (222), (400) and (440) planes are observed by X-ray diffraction. Amorphous encompass those in which no X-ray crystal diffraction peak is observed, even though crystal grains can be observed by high-resolution observation with a TEM or the like. An amorphous film has a moisture vapor transmission rate lower than that of a crystalline film. Thus, when the light-receiving-side transparent electroconductive layer 3 is amorphous, reliability of the photoelectric conversion device can be kept high even if the perovskite material in the light absorbing layer, the organic material in the hole transporting layer, or the like has low water resistance. On the other hand, the light-receiving-side transparent electroconductive layer 3 is preferably crystalline for reducing contact resistance with the hole transporting layer 12. When the transparent electroconductive layer 3 is crystalline, the short circuit current in the first photoelectric conversion unit tends to increase because the bandgap increases, leading to a decrease in absorption of short-wavelength light.

The transparent electroconductive layer is formed by a dry process (a CVD method or a PVD method such as a sputtering method or an ion plating method). A PVD method such as a sputtering method or an ion plating method is preferred for formation of a transparent electroconductive layer mainly composed of an indium-based oxide. Sputtering deposition is carried out with introducing a carrier gas containing an inert gas such as argon or nitrogen, and an oxygen gas into a deposition chamber. The amount of oxygen introduced into the deposition chamber is preferably 0.1 to 10% by volume, more preferably 1 to 5% by volume based on the total amount of the introduced gas. The mixed gas may contain other gases.

The carrier density, the work function and the crystallinity of the light-receiving-side transparent electroconductive layer 3 can be appropriately adjusted by changing the material of the conductive oxide, the composition, and deposition conditions (substrate temperature, type and introduction amount of introduction gas, deposition pressure, power density and so on). Conductive carriers in the transparent electroconductive layer are derived from a heterogeneous element contained mainly as a dopant, and oxygen deficiency. Thus, when the introduction amount of an oxidizing gas such as oxygen is reduced, and the substrate temperature is lowered, the carrier density tends to increase (the work function tends to decrease). When the amount of a heterogeneous element (e.g., tin in ITO) is increased, the carrier density tends to increase (the work function tends to decrease). The value of the carrier density varies depending on which of the dopant amount and the oxygen deficiency amount is a dominant factor of determining the carrier density, and therefore the production parameter effective for adjustment of the carrier density varies depending on the type and the amount of a dopant, and various kinds of other deposition conditions.

When the hole transporting layer 12 and the light absorbing layer 11 that are provided below the light-receiving-side transparent electroconductive layer 3 are damaged during deposition of the light-receiving-side transparent electroconductive layer 3, the characteristics of the first photoelectric conversion unit 1 are deteriorated. For reducing damage during the deposition, the pressure (total pressure) in the deposition chamber during deposition of the light-receiving-side transparent electroconductive layer 3 is preferably 0.1 to 1.0 Pa, and the power density is preferably 0.2 to 1.2 mW/cm². In general, an amorphous film is easily obtained when the pressure during deposition is increased, or the power density is decreased.

(Second Photoelectric Conversion Unit)

The second photoelectric conversion unit 2 is a photoelectric conversion unit having a bandgap narrower than that of the first photoelectric conversion unit 1. The configuration of the second photoelectric conversion unit 2 is not particularly limited as long as the bandgap of the light absorbing layer thereof is narrower than the bandgap of the light absorbing layer in the first photoelectric conversion unit 1. Examples of material for the light absorbing layer having a bandgap narrower than that of a perovskite material include crystalline silicon, gallium arsenide (GaAs), and CuInSe₂ (CIS). Among these, crystalline silicon and CIS are preferable in view of high utilization efficiency of long-wavelength light (particularly infrared light having wavelengths of 1000 nm or longer). Crystalline silicon may be single-crystalline, polycrystalline, or microcrystalline. In particular, due to high utilization efficiency of long-wavelength light and excellent carrier collection efficiency, the second photoelectric conversion unit 2 preferably includes a single-crystalline silicon substrate as the light absorbing layer.

Examples of photoelectric conversion unit having a single-crystalline silicon substrate include one in which a highly doped region is provided on a surface of a single-crystalline silicon substrate; and one in which silicon-based thin-films are provided on both surfaces of a single-crystalline silicon substrate (so called heterojunction silicon solar cell). In particular, the second photoelectric conversion unit is preferably a heterojunction unit because of its high conversion efficiency.

The photoelectric conversion device 110 shown in FIG. 1 contains a heterojunction unit as the second photoelectric conversion unit 2 in which conductive silicon-based thin-films 24 and 25, respectively, are provided on the surfaces of the single-crystalline silicon substrate 21. The conductive silicon-based thin-film 24 on the light-receiving side has p-type conductivity, and the conductive silicon-based thin-film 25 on the rear side has n-type conductivity. The conductivity-type of the single-crystalline silicon substrate 21 may be either an n-type or a p-type. In comparison between electron and hole, electron has a higher mobility, and thus when the silicon substrate 21 is an n-type single-crystalline silicon substrate, the conversion characteristic is particularly high.

The silicon substrate 21 may have a texture (a plurality of projections or recesses) on a surface. For example, tetragonal pyramid-shaped textured structure can be formed on a surface of a single-crystalline silicon substrate by anisotropic etching. When a texture is provided on a light-receiving surface of the silicon substrate, reflection of light to the first photoelectric conversion unit 1 can be reduced. The height of the projections or recesses is preferably 0.5 μm or more, more preferably 1 μm or more. The height of the projections or recesses is preferably 3 μm or less, more preferably 2 μm or less. When the height of the projections or recesses is in the above-mentioned range, the reflectance of a surface of the substrate can be reduced to increase a short circuit current. The height of the projections or recesses on the surface of the silicon substrate 21 is determined by a height difference between the peak of the projection and the valley of the recess.

When the second photoelectric conversion unit 2 is a heterojunction unit, it is preferable that the photoelectric conversion unit includes intrinsic silicon-based thin-films 22 and 23 between the single-crystalline silicon substrate 21 and the conductive silicon-based thin-films 24 and 25. By providing the intrinsic silicon-based thin-film on the surface of the single-crystalline silicon substrate, surface passivation can be effectively performed while diffusion of impurities to the single-crystalline silicon substrate is suppressed. For effectively performing surface passivation of the single-crystalline silicon substrate 21, the intrinsic silicon-based thin-films 22 and 23 are preferably intrinsic amorphous silicon thin-films.

As the conductive silicon-based thin-films 24 and 25, amorphous silicon, microcrystalline silicon (material including amorphous silicon and crystalline silicon), amorphous silicon alloy and microcrystalline silicon alloy may be used. Examples of the silicon alloy include silicon oxide, silicon carbide, silicon nitride silicon germanium and the like. Among the above, conductive silicon-based thin-film is preferably an amorphous silicon thin-film. The above intrinsic silicon-based thin-films 22 and 23, and conductive silicon-based thin-films 24 and 25 can be formed by a plasma-enhanced CVD method.

(Rear-Side Transparent Electroconductive Layer and Intermediate Transparent Electroconductive Layer)

When the second photoelectric conversion unit 2 is a heterojunction unit, the rear-side transparent electroconductive layer 32 mainly composed of a conductive oxide is provided on the n-type silicon-based thin-film 25 on the rear side. Preferably, the intermediate transparent electroconductive layer 31 mainly composed of a conductive oxide is provided between the first photoelectric conversion unit 1 and the second photoelectric conversion unit 2, i.e., on the p-type silicon-based thin-film 24 on the light-receiving side. The transparent electroconductive layer 31 has a function as an intermediate layer which captures and recombines holes and electrons generated in the two photoelectric conversion units 1 and 2. The preferred material and formation method for the rear-side transparent electroconductive layer 32 and the intermediate transparent electroconductive layer 31 are the same as the preferred material and formation method for the transparent electroconductive layer 3.

(Metal Electrode)

It is preferred that, as shown in FIG. 1, the photoelectric conversion device 110 includes metal collecting electrodes 5 and 6 on transparent electroconductive layers 3 and 32, respectively, for effectively extracting photo carriers. The collecting electrode 5 on the light-receiving side is formed in a predetermined pattern shape. The rear-side metal electrode 6 may be formed in a pattern shape, or formed on substantially the entire surface of the rear-side transparent electroconductive layer 32. In the embodiment shown in FIG. 1, the collecting electrode 5 is formed in a pattern shape on the light-receiving-side transparent electroconductive layer 3, and the rear-side metal electrode 6 is formed on the entire surface of the rear-side transparent electroconductive layer 32.

Examples of the method for forming a rear-side metal electrode on the entire surface of a rear-side transparent electroconductive layer 32 include dry processes such as various kinds of PVD methods and CVD methods, application of a paste, and a plating method. For the rear-side metal electrode, it is desirable to use a material which has a high reflectivity of light having a wavelength in a near-infrared to infrared range and which has high electroconductivity and chemical stability. Examples of the material having the above-mentioned properties include silver, copper and aluminum.

The patterned collecting electrode is formed by a method of applying an electroconductive paste, a plating method, or the like. When an electroconductive paste is used, the collecting electrode is formed by ink-jetting, screen printing, spraying or the like. Screen printing is preferable from the viewpoint of productivity. In screen printing, a process of applying an electroconductive paste containing metallic particles and a resin binder by screen printing is preferably used. When a collecting electrode is formed in a pattern shape by a plating method, it is preferable that a metal seed layer is formed in a pattern shape on the transparent electroconductive layer, and a metal layer is then formed by a plating method with the metal seed layer as an origination point. In this method, it is preferable that an insulating layer is formed on the transparent electroconductive layer for suppressing deposition of a metal on the transparent electroconductive layer.

### Other Embodiments

The configurations of the photoelectric conversion units described with reference to FIG. 1 are illustrative, and the photoelectric conversion units may include other layers. For example, it is preferred that an anti-reflection film composed of, for example, MgF₂ is formed on the light-receiving-side transparent electroconductive layer 3.

The solar cell that forms the second photoelectric conversion unit is not limited to a heterojunction solar cell as long as it is a solar cell having a bandgap narrower than that of a solar cell that forms the first photoelectric conversion unit as described above.

In FIG. 1, a double-junction photoelectric conversion device in which a first photoelectric conversion unit and a second photoelectric conversion unit are stacked in this order has been described as an example, but other stacking configurations can be employed. For example, the photoelectric conversion device according to the present invention may be a triple-junction photoelectric conversion device including other photoelectric conversion unit at the rear of the second photoelectric conversion unit, or may be a quadruple-or-more junction photoelectric conversion device. The bandgap of the light absorbing layer in the photoelectric conversion unit disposed on the rear side is preferably narrower than the bandgap of the light absorbing layer in the photoelectric conversion unit disposed on the front side.

The photoelectric conversion device of the present invention is preferably sealed by a sealing material and modularized when put into practical use. Modularization of the photoelectric conversion device is performed by an appropriate method. For example, modularization is performed by connecting collecting electrode via an interconnector such as a TAB to a collecting electrode, so that a plurality of solar cells are connected in series or in parallel, and encapsulated with an encapsulant and a glass plate.

### DESCRIPTION OF REFERENCE CHARACTERS

1 first photoelectric conversion unit
11 light absorbing layer
12 hole transporting layer
13 electron transporting layer
2 second photoelectric conversion unit
21 conductive single-crystalline silicon substrate
22, 23 intrinsic silicon-based thin-film
24, 25 conductive silicon-based thin-film
3, 31, 32 transparent electroconductive layer
5 collecting electrode
6 rear-side metal electrode
110 photoelectric conversion device

What is claimed is:

1. A photoelectric conversion device comprising, arranged in the following order from a light-receiving side:
a transparent electroconductive layer;
a first photoelectric conversion unit that is a perovskite-type photoelectric conversion unit; and
a second photoelectric conversion unit,
wherein the first photoelectric conversion unit comprises, arranged in the following order from the light-receiving side:
a hole transporting layer;
a light absorbing layer comprising a photosensitive material of perovskite-type crystal structure represented by general formula RNH₃MX₃ or HC(NH₂)₂MX₃, wherein R is an alkyl group, M is a divalent metal ion, and X is a halogen; and
an electron transporting layer,
wherein the second photoelectric conversion unit comprises a light absorbing layer having a bandgap narrower than a bandgap of the light absorbing layer in the first photoelectric conversion unit,
wherein a product of a resistivity ρ and a thickness t of the hole transporting layer in the first photoelectric conversion unit satisfies ρt≧0.1 μΩ·m², and
wherein the transparent electroconductive layer is in contact with the hole transporting layer.

2. The photoelectric conversion device according to claim 1, wherein a work function of the transparent electroconductive layer is 4.7 to 5.8 eV

3. The photoelectric conversion device according to claim 1, wherein a carrier density of the transparent electroconductive layer is 1×10¹⁹ to 5×10²⁰ cm⁻³.

4. The photoelectric conversion device according to claim 1, wherein a thickness of the hole transporting layer in the first photoelectric conversion unit is 1 to 100 nm.

5. The photoelectric conversion device according to claim 1, wherein the light absorbing layer in the second photoelectric conversion unit is crystalline silicon.

6. The photoelectric conversion device according to claim 1,
wherein the second photoelectric conversion unit further comprises, arranged in the following order from the light-receiving side: a p-type silicon-based thin-film; and an n-type silicon-based thin-film, and
wherein the light absorbing layer of the second photoelectric conversion unit is a conductive single-crystalline silicon substrate arranged between the p-type silicon-based thin-film and the n-type silicon-based thin-film.

7. A photoelectric conversion module comprising the photoelectric conversion device according to claim 1.

8. A method for manufacturing a photoelectric conversion device, the method comprising:
preparing a second photoelectric conversion unit comprising a light absorbing layer;
forming a first photoelectric conversion unit by providing, in the following order, an electron transporting layer, a light absorbing layer and a hole transporting layer, on the second photoelectric conversion unit; and
forming a transparent electroconductive layer on the hole transporting layer in the first photoelectric conversion unit,
wherein a bandgap of the light absorbing layer in the second photoelectric conversion unit is narrower than a bandgap of the light absorbing layer in the first photoelectric conversion unit,
wherein the light absorbing layer in the first photoelectric conversion unit comprises a photosensitive material of perovskite-type crystal structure represented by general formula RNH₃MX₃ or HC(NH₂)₂MX₃, wherein R is an alkyl group, M is a divalent metal ion, and X is a halogen,
wherein a product of a resistivity ρ and a thickness t of the hole transporting layer in the first photoelectric conversion unit satisfies ρt≧0.1 μΩ·m², and
wherein the transparent electroconductive layer is in contact with the hole transporting layer.
